(19) United States
(12) Patent Application Publication
(10) Pub. No.: US 2024/0162323 A1
(43) Pub. Date: May 16, 2024

(54) INTEGRATED CIRCUIT DEVICE

(71) Applicant: Samsung Electronics Co., Ltd., Suwon-si (KR)

(72) Inventors: Junghoo Shin, Suwon-si (KR); Sangcheol Na, Suwon-si (KR); Minjae Kang, Suwon-si (KR); Yongjin Kwon, Suwon-si (KR); Soeun Kim, Suwon-si (KR); Jongmin Baek, Suwon-si (KR)

(21) Appl. No.: 18/489,220

(22) Filed: Oct. 18, 2023

(30) Foreign Application Priority Data
Nov. 16, 2022 (KR) 10-2022-0153809

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H01L 29/42392; H01L 21/823475; H01L 27/088; H01L 29/0673; H01L 29/0847; H01L 29/66439; H01L 29/66545; H01L 29/775; H01L 29/78696

(57) ABSTRACT

The integrated circuit device includes a substrate, a first fin extending in a first horizontal direction on the substrate, a second fin and a third fin spaced apart from each other in the first horizontal direction and extending in the first horizontal direction, a second source/drain area on the second fin and the third fin, a back side contact between the second fin and the third fin and electrically connected to the second source/drain area, and a back side conductive layer extending in the first horizontal direction and electrically connected to the back side contact. The back side contact includes a first portion protruding from the substrate and a second portion that is coplanar, in a vertical direction, with the substrate. A width of the second portion in the second horizontal direction is greater than a width of the first portion in the second horizontal direction.

### CROSS-REFERENCE TO RELATED APPLICATION

This application is based on and claims priority under 35 U.S.C. § 119 to Korean Patent Application No. 10-2022-0153809, filed on Nov. 16, 2022, in the Korean Intellectual Property Office, the disclosure of which is incorporated by reference herein in its entirety.

### BACKGROUND

The inventive concept relates to an integrated circuit device, and more particularly, to an integrated circuit device including a self-align structure.

As the recent electronic products require a smaller size, a multi-function and high performance, the integrated circuit devices are also required to have high capacity and high degree of integration. Accordingly, there has been demand for efficient wiring structures for achieving a high degree of integration and performing required operations of the integrated circuit device with a designed speed.

### SUMMARY

The inventive concept, as manifested in one or more embodiments, provides an integrated circuit device having improved integration and reliability.

According to an aspect of the inventive concept, there is provided an integrated circuit device including a substrate having a first surface and a second surface, a first fin extending in a first horizontal direction on the first surface of the substrate, a second fin spaced apart from the first fin in a second horizontal direction crossing the first horizontal direction and extending in the first horizontal direction, a third fin spaced apart from the second fin in the first horizontal direction and extending in the first horizontal direction overlapping the second fin in the first horizontal direction, a first source/drain area arranged on the first fin, a second source/drain area arranged on the second fin and the third fin and spaced apart from the first source/drain area in a second horizontal direction, a back side contact positioned between the second fin and the third fin and electrically connected to the second source/drain area, and a back side conductive layer extending in the first horizontal direction on the second surface of the substrate and electrically connected to the back side contact. In such a case, the back side contact may include a first portion protruding from the substrate and a second portion positioned at a same vertical level as the substrate, and a width of the second portion in the second horizontal direction may be greater than a width of the first portion in the second horizontal direction.

According to another aspect of the inventive concept, there is provided an integrated circuit device including a substrate having a first surface and a second surface, a fin-type active region extending in a first horizontal direction on the first surface of the substrate, a plurality of gate lines extending in a second horizontal direction crossing the first horizontal direction on the fin-type active region and spaced apart from each other in the first horizontal direction, a back side contact positioned between the plurality of gate lines and overlapping the fin-type active region in the second horizontal direction, a source/drain area positioned on the back side contact, and a back side conductive layer extending in the first horizontal direction on the second surface of the substrate. In such a case, the back side contact may be electrically connected to the source/drain area and the back side conductive layer, and the back side contact may include a first portion protruding from the substrate and a second portion positioned at the same vertical level as the substrate. A width of the second portion in the second horizontal direction may be greater than a width of the first portion in the second horizontal direction.

According to another aspect of the inventive concept, there is provided an integrated circuit device including a substrate having a first surface and a second surface, a fin-type active region extending in a first horizontal direction on the first surface of the substrate, a plurality of nanosheets on the fin-type active region and spaced apart from an upper surface of the fin-type active region in a vertical direction, a gate line surrounding the plurality of nanosheets on the fin-type active region and extending in a second horizontal direction crossing the first horizontal direction, a back side contact positioned on one side of the gate line and overlapping the fin-type active region in the second horizontal direction, a first source/drain area positioned on the fin-type active region and contacting the plurality of nanosheets, a second source/drain area positioned on the back side contact and contacting the plurality of nanosheets, and a back side conductive layer extending in the first horizontal direction on the second surface of the substrate. In such a case, the back side contact may be electrically connected to the second source/drain area and the back side conductive layer, and the back side contact may include a first portion protruding from the substrate and a second portion positioned at the same vertical level as the substrate. A width of the second portion in the second horizontal direction may be greater than a width of the first portion in the second horizontal direction.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a view illustrating a planar layout of an exemplary cell block of an integrated circuit device according to an embodiment;

FIG. 2 is a diagram showing a planar layout of an integrated circuit device according to an embodiment;

FIGS. 3A to 3C are cross-sectional views illustrating an integrated circuit device according to an embodiment;

FIG. 4 is a diagram showing a planar layout of an integrated circuit device according to another embodiment;

FIG. 5 is a cross-sectional view illustrating the integrated circuit device according to another embodiment;

FIG. 6 is a diagram showing a planar layout of an integrated circuit device according to another embodiment;

FIG. 7 is a cross-sectional view illustrating an integrated circuit device according to another embodiment; and

FIGS. 8 to 19 are cross-sectional views illustrating intermediate processes in an example method of manufacturing an integrated circuit device according to an embodiment, in a process order.

### DETAILED DESCRIPTION OF THE EMBODIMENTS

Hereinafter, illustrative embodiments of the inventive concept will be described in detail with reference to the accompanying drawings. The same reference numerals denote the same elements throughout the several views in the drawings, and duplicate descriptions of the same elements are omitted.

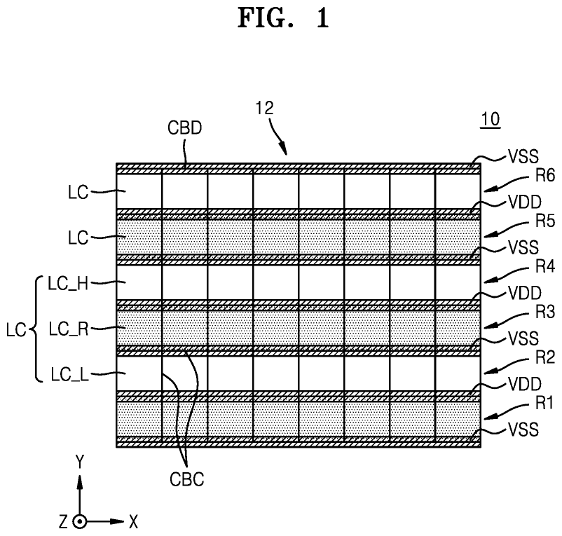

FIG. 1 is a view illustrating a planar layout of an exemplary cell block 12 of an integrated circuit device 10 according to an embodiment.

Referring to FIG. 1, a cell block 12 of an integrated circuit device 10 may include a plurality of logic cells LC having circuit patterns for various circuits. A least a subset of the plurality of logic cells LC may be arranged in a matrix form in the cell block 12 along a first horizontal direction (X direction) and a second horizontal direction (Y direction).

Each of the logic cells LC may include a circuit pattern having a layout designed by a Place and Route (PnR) technique for performing at least one logic function. A plurality of logic cells LC may perform various logic functions. In embodiments, a plurality of logic cells LC may include a plurality of standard cells. In one or more embodiments, at least some of a plurality of logic cells LC may perform the same logic function. In other embodiments, at least some of a plurality of logic cells LC may perform different logic functions.

The plurality of logic cells LC may include various types of logic cells having a plurality of circuit elements. For example, at least a subset of the plurality of logic cells LC may include any one of an AND circuit, a NAND circuit, an OR circuit, a NOR circuit, an exclusive OR (XOR) circuit, an exclusive NOR (XNOR) circuit, an inverter (INV) circuit, an adder (ADD) circuit, a buffer (BUF) circuit, a delay (DLY) circuit, a filter (FIL) circuit, a multiplexer (MXT/MXIT) circuit, an OAI (OR/AND/INVERTER) circuit, an AO (AND/OR) circuit, an AOI(AND/OR/INVERTER) circuit, a D flip-flop circuit, a reset flip-flop circuit, a master-slave flip-flop circuit, a latch circuit, or a combination thereof, but is not limited thereto.

In the cell block 12, at least some of the plurality of logic cells LC arranged in any one row R1, R2, R3, R4, R5, or R6 in the first horizontal direction (X direction) may have the same width. In addition, at least some of the plurality of logic cells LC in any row R1, R2, R3, R4, R5, or R6 may have the same height. However, the technical idea of the inventive concept is not limited to the illustration of FIG. 1, and at least some of the plurality of logic cells LC arranged in any one row R1, R2, R3, R4, R5, or R6 may have different widths and/or heights.

A cell area of each of the logic cells LC in the cell block 12 of the integrated circuit device 10 may be defined by a cell boundary CBD. A cell contact portion CBC where each cell boundary CBD meets may be provided between two adjacent logic cells LC in the first horizontal direction (X direction) and/or in the second horizontal direction (Y direction) among the plurality of logic cells LC.

In some embodiments, two logic cells LC adjacent to each other along the first horizontal direction in any one row R1, R2, R3, R4, R5, or R6 may be in direct contact with each other just at the cell contact portion CBC without any gap distance therebetween. In other embodiments, two logic cells LC adjacent to each other along the first horizontal direction in any one row R1, R2, R3, R4, R5, or R6 may be spaced apart from each other with a certain gap distance therebetween.

In some embodiments, two logic cells LC adjacent to each other in any one row R1, R2, R3, R4, R5, or R6 may perform the same function. In this case, the two adjacent logic cells LC may have the same structure. In other embodiments, two logic cells LC adjacent to each other in any one row R1, R2, R3, R4, R5, or R6 may perform different functions.

In some embodiments, a logic cell LC selected from the logic cells LC in the cell block 12 of the integrated circuit device 10 and another logic cell LC adjacent to the selected logic cell LC in the second horizontal direction (Y direction in FIG. 1) may have a symmetrical structure with respect to the cell contact portion CBC. For example, a reference logic cell LC_R in a third row R3 and a lower logic cell LC_L in a second row R2 may have a symmetrical structure with respect to the cell contact portion CBC therebetween. In addition, the reference logic cell LC_R in the third row R3 and an upper logic cell LC_H in the fourth row R4 may have a symmetrical structure with respect to the cell contact portion CBC therebetween.

Although the cell block 12 is illustrated to include six rows R1, R2, . . . , R6 in FIG. 1, this is only an example, and the cell block 12 may include various numbers of rows (e.g., more than or less than six rows) selected as necessary, and a single row may include various numbers of logic cells selected as necessary.

A single line selected from a plurality of ground lines VSS and a plurality of power lines VDD may be positioned (i.e., disposed or located) at each gap space between any pair of two adjacent rows R1, R2, R3, R4, R5, and R6 each in which a plurality of logic cells LC may be arranged in a line along the first horizontal direction (X direction). The plurality of ground lines VSS and the plurality of power lines VDD may extend in a first horizontal direction (X direction), and the ground line VSS and the power line VDD may be alternately positioned with each other and spaced apart from each other in a second horizontal direction (Y direction). Accordingly, the plurality of ground lines VSS and the plurality of power lines VDD may be positioned to overlap the cell boundary CBD along the second horizontal direction Y of the logic cell LC, respectively.

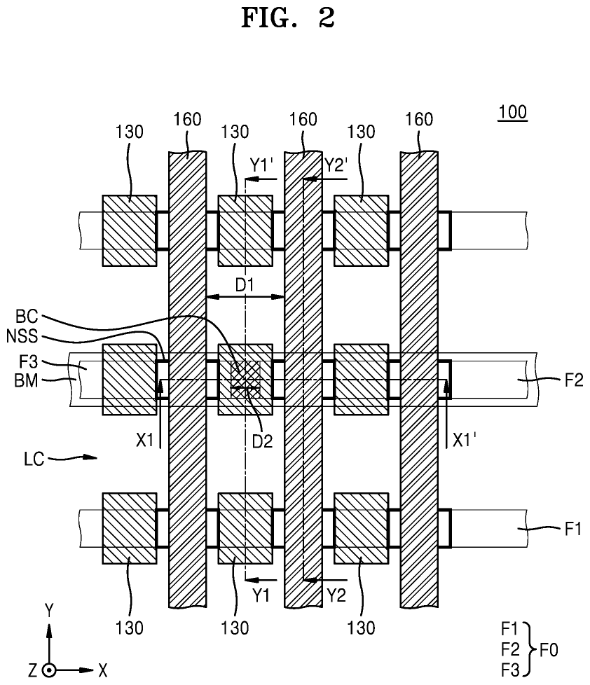

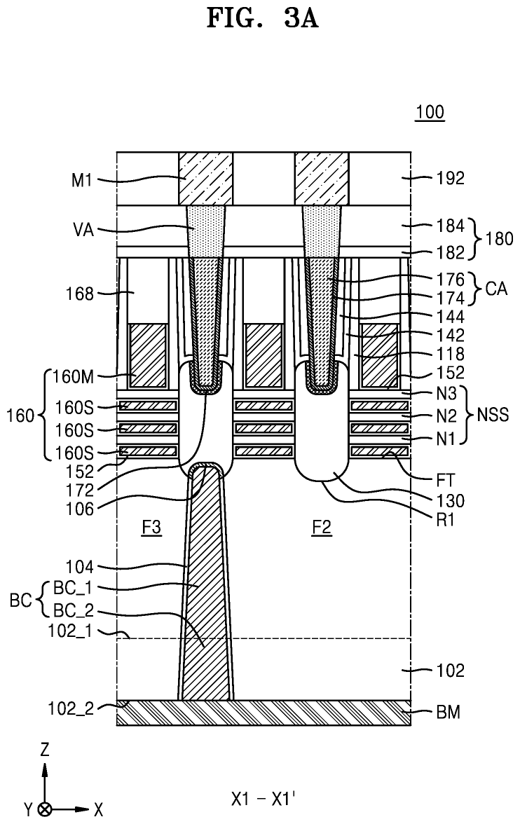

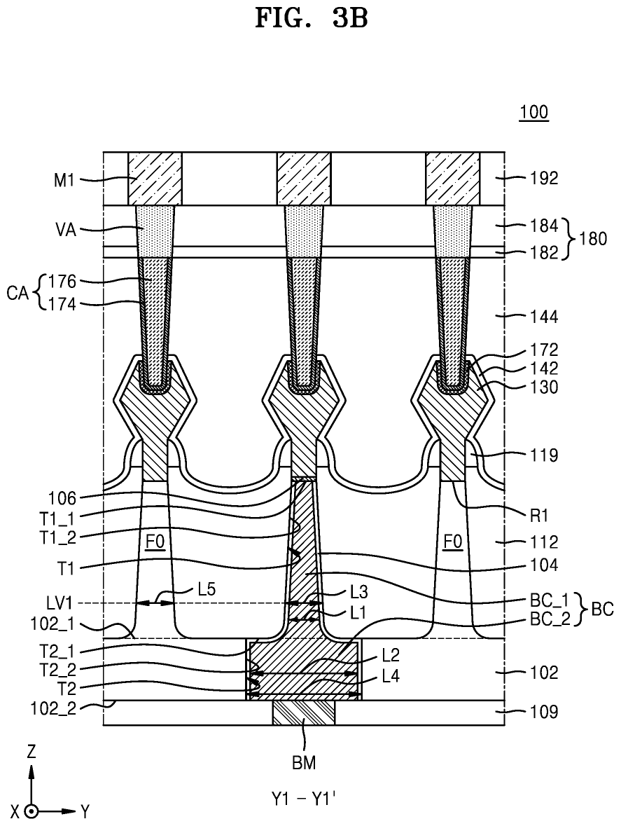

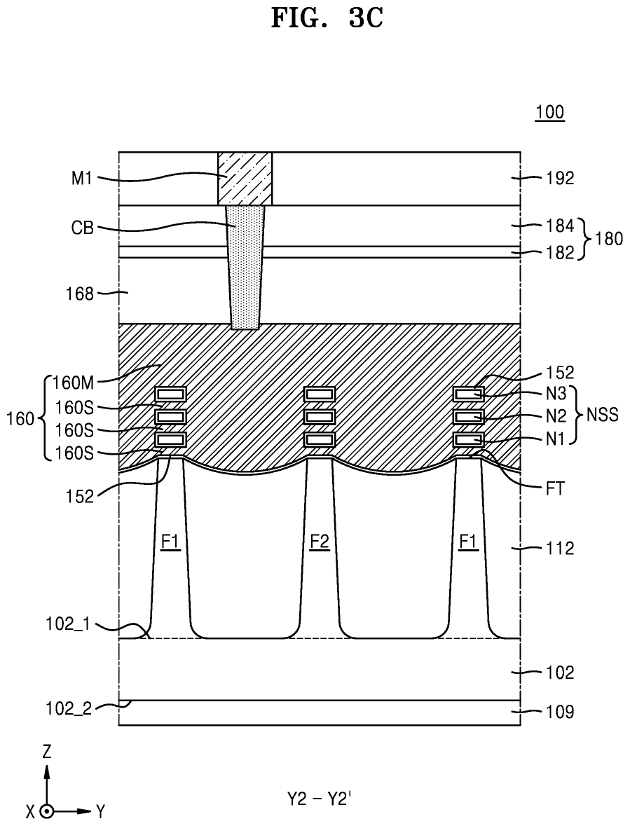

FIG. 2 is a diagram showing a planar layout of an integrated circuit device 100 according to an embodiment. FIGS. 3A to 3C are cross-sectional views illustrating an integrated circuit device 100 according to an embodiment. Specifically, FIG. 3A is a cross-sectional view taken along a line X1-X1′ in FIG. 2. FIG. 3B is a cross-sectional view taken along a line Y1-Y1′ in FIG. 2. FIG. 3C is a cross-sectional view taken along a line Y2-Y2′ in FIG. 2.

Referring to FIGS. 2 and 3A to 3C, an integrated circuit device 100 may include a field-effect transistor having an active region shaped into a nanowire or nanosheet and a gate enclosing the active region and configured as a gate-all-around structure, and the integrated circuit device 100 is described in further detail hereinafter. The integrated circuit device 100 may be provided as some of the plurality of logic cells LC illustrated in FIG. 1.

The integrated circuit device 100 may include a substrate 102 having a first surface 102_1 and a second surface 102_2, opposite the first surface 102_1, and a plurality of fin-type active regions F0 protruding from the first surface 102_1 of the substrate 102. The plurality of fin-type active regions F0 may extend along and parallel to each other in the first horizontal direction (X direction) on the substrate 102.

The substrate 102 may include a semiconductor such as, for example, silicon (Si) or germanium (Ge), or a compound semiconductor such as silicon germanium (SiGe), silicon carbide (SiC), gallium arsenide (GaAs), indium arsenide (InAs), indium gallium arsenide (InGaAs), or indium phosphorus (InP), although embodiments of the invention are not limited thereto. The terms “SiGe”, “SiC”, “GaAs”, “InAs”, “InGaAs”, and “InP” used in this specification refer to materials composed of elements included in each term, and are not a chemical formula representing a stoichiometric relationship. The substrate 102 may include a conductive region, for example, a well doped with impurities, or a doped structure doped with impurities.

A device isolation layer 112 may be positioned in a trench defining the plurality of fin-type active regions F0. The device isolation layer 112 may cover portions of the side walls of each fin-type active region F0 and may be spaced apart from the substrate 102 in a vertical direction (Z direction). The device isolation layer 112 may include a silicon oxide layer, or other insulating material. The device isolation layer 112 may be made of a material having an etching selectivity different from that of the substrate 102.

The second surface 102_2 of the substrate 102 may be covered with a back side insulating layer 109. The back side insulating layer 109 may include, for example, a silicon oxide layer, a silicon nitride layer, a silicon carbide layer, a low dielectric layer, or a combination thereof. The low dielectric layer may include, for example, fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but is not limited thereto.

As illustrated in FIGS. 2, 3A, and 3C, a plurality of gate lines 160 may be positioned on the plurality of fin-type active regions F0. The plurality of gate lines 160 may extend along in the second horizontal direction (Y direction) crossing the first horizontal direction (X direction), respectively. In areas where the plurality of fin-type active regions F0 and the plurality of gate lines 160 cross, a plurality of nanosheet stacks NSS may be positioned on fin upper surfaces FT of each fin-type active region F0. Each of the nanosheet stacks NSS may include at least one nanosheet facing the fin upper surface FT at a location spaced apart from the fin upper surface FT of the fin type active region F0 in the vertical direction (Z direction). The term “nanosheet” used in the present specification is intended to refer broadly to a conductive structure having a cross section substantially perpendicular to a direction in which a current flows. The nanosheet should be understood to include the nanowires.

As illustrated in FIGS. 3A and 3C, each of the plurality of nanosheet stacks NSS may include a first nanosheet N1, a second nanosheet N2, and a third nanosheet N3 overlapping each other in the vertical direction (Z direction) on the fin-type active region F0. The first nanosheet N1, the second nanosheet N2, and the third nanosheet N3 may have different vertical distances (distance in the Z direction) from the fin upper surface FT of the fin-type active region F0. A plurality of gate lines 160 may enclose the first nanosheet N1, the second nanosheet N2, and the third nanosheet N3 of the nanosheet stack NSS that are overlapped in the vertical direction (Z direction), respectively. Components, structures or layers described herein with reference to the term “overlapping” (or “overlap”) in a particular direction may be at least partially obstructed by one another when viewed along a line extending in a particular direction or in a plane perpendicular to the particular direction.

Although a planar shape of the nanosheet stack NSS is illustrated to be substantially rectangular in FIG. 2, the planar shape of the nanosheet stack NSS is not limited to a rectangular shape. The nanosheet stack NSS may have various planar shapes according to planar shapes of the fin-type active region F0 and the gate line 160. In an embodiment, a plurality of nanosheet stacks NSS and a plurality of gate lines 160 are positioned on a single fin-type active region F0, and a plurality of nanosheet stacks NSS may be positioned in a line along the first horizontal direction (X direction) on the single fin-type active region F0. However, the number of the nanosheet stacks NSS and the gate lines 160 on a single fin-type active region F0 is not particularly limited.

The first nanosheet N1, the second nanosheet N2, and the third nanosheet N3 of the nanosheet stack NSS may function as a channel region, respectively. In embodiments, each of the first nanosheet N1, the second nanosheet N2, and the third nanosheet N3 may have a thickness in a range of about 4 nanometers (nm) to about 6 nm, but is not limited thereto. Herein, the thickness of each of the first nanosheet N1, the second nanosheet N2, and the third nanosheet N3 denotes a size or a length in the vertical direction (Z direction); that is, a cross-sectional thickness. In embodiments, the first nanosheet N1, the second nanosheet N2, and the third nanosheet N3 may have substantially the same thickness in the vertical direction (Z direction). In other embodiments, at least some of the first nanosheet N1, the second nanosheet N2, and the third nanosheet N3 may have different thicknesses in the vertical direction (Z direction) relative to one another. In embodiments, the first nanosheet N1, the second nanosheet N2, and the third nanosheet N3 of the nanosheet stack NSS may include a silicon (Si) layer, a silicon germanium (SiGe) layer, or a combination thereof, respectively.

As illustrated in FIG. 3A, the first nanosheet N1, the second nanosheet N2, and the third nanosheet N3 of a single nanosheet stack NSS may have the same or similar sizes in the first horizontal direction (X direction). In other embodiments, unlike the embodiment illustrated in FIG. 3A, at least some of the first nanosheet N1, the second nanosheet N2, and the third nanosheet N3 of the single nanosheet stack NSS may have different sizes in the first horizontal direction (X direction) relative to one another. Although the present embodiment discloses that the nanosheet stacks NSS includes three nanosheets, the number of the nanosheet of the single nanosheet stack NSS is not limited to three. For example, the nanosheet stack NSS may include at least one nanosheet, and the number of the nanosheet of the nanosheet stack NSS may not be particularly limited.

As illustrated in FIGS. 3A and 3C, each of the gate lines 160 may include a main gate portion 160M and a plurality of sub-gate portions 160S. The main gate portion 160M may cover an upper surface of the nanosheet stack NSS and extend along in the second horizontal direction (Y direction). The plurality of sub-gate portions 160S may be integrally connected to the main gate portion 160M and be positioned between the third nanosheet N3 and the second nanosheet N2, between the second nanosheet N2 and the first nanosheet N1, and between the first nanosheet N1 and the fin-type active region F0. The thickness of each sub-gate portion 160S in the vertical direction (Z direction) may be smaller than that of the main gate portion 160M.

Each gate line 160 may include a conductive material, such as, for example, a metal, a metal nitride, a metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum nitride (TaN). The metal carbide may include titanium aluminum carbide (TiAlC). However, the material of the gate line 160 is not limited to the type of conductive material described above.

As illustrated in FIGS. 3A and 3B, a plurality of recesses R1 may be arranged on the fin-type active region F0. The vertical level (i.e., height above the substrate 102) of the lowest surface of each recess R1 may be lower than that of the fin upper surface FT of the fin-type active region F0.

As illustrated in FIGS. 3A and 3B, a plurality of source/drain areas 130 may be positioned in the plurality of recess R1. The plurality of source/drain areas 130 may be located at positions adjacent to at least one gate line 160 selected from the plurality of gate lines 160, respectively. Each of the source/drain areas 130 may have surfaces facing the first nanosheet N1, the second nanosheet N2, and the third nanosheet N3 of the nanosheet stack NSS adjacent thereto, respectively. Each of the source/drain areas 130 may be in contact with the first nanosheet N1, the second nanosheet N2, and the third nanosheet N3 of the nanosheet stack NSS adjacent thereto, respectively.

As illustrated in FIGS. 2 and 3C, the plurality of fin-type active regions F0 of the integrated circuit device 100, which is protruded from the first surface 102_1 of the substrate 102, may include a first fin F1, a second fin F2, and a third fin F3 extending in the first horizontal direction (X direction). The first fin F1 may extend in the first horizontal direction (X direction) on the substrate 102. The second fin F2 and the third fin F3 may be spaced apart from the first fin F1 in the second horizontal direction (Y direction) and may extend in the first horizontal direction (X direction) on the substrate 102. The second fin F2 and the third fin F3 may be spaced apart from each other in the first horizontal direction (X direction) and may overlap each other in the first horizontal direction (X direction). The second fin F2 and the third fin F3 may overlap with the first fin F1 in the second horizontal direction (Y direction), respectively.

As illustrated in FIGS. 2, 3A, and 3B, the integrated circuit device 100 may include a back side contact BC overlapping with the plurality of fin-type active regions F0 in the second horizontal direction (Y direction). Specifically, the back side contact BC may overlap with the first fin F1 in the second horizontal direction (Y direction). Specifically, the back side contact BC may overlap with the second fin F2 and the third fin F3 in the first horizontal direction (X direction). The back side contact BC may be positioned between the second fin F2 and the third fin F3 in the first horizontal direction (X direction).

In some embodiments, the back side contact BC may include a metal wiring layer (not explicitly illustrated, but implied) and a conductive barrier layer (not explicitly illustrated, but implied) enclosing the metal wiring layer. The metal wiring layer may include ruthenium (Ru), cobalt (Co), tungsten (W), or a combination thereof. The conductive barrier layer may include Ti, TiN, tantalum (Ta), TaN, or a combination thereof.

Specifically, the back side contact BC may be positioned between the gate lines 160. The gate lines 160 may be spaced apart from each other with the back side contact BC interposed therebetween. Thus, the distance D1 between the neighboring (i.e., adjacent) gate lines 160 may be greater than a width D2 of the back side contact BC in the first horizontal direction (X direction).

In some embodiments, the back side contact BC may include a portion extending, in the vertical direction (Z direction), at least partially through the substrate 102. The back side contact BC may penetrate the substrate 102 and may be protruded from the first surface 102_1 of the substrate 102 in the vertical direction (Z direction). Specifically, the back side contact BC may include a first portion BC_1 protruding from the first surface 102_1 of the substrate 102 in the vertical direction (Z direction) and a second portion BC_2 penetrating the substrate 102 at the same vertical level as the substrate 102. The first portion BC_1 of the back side contact BC may overlap with the first fin F1 in the second horizontal direction (Y direction).

In some embodiments, a width L1 of the first portion BC_1 of the back side contact BC in the second horizontal direction (Y direction) may be smaller than a width L2 of the second portion BC_2 of the back side contact BC in the second horizontal direction (Y direction). That is, a sidewall of the back side contact BC may have a stepped portion. Thus, the sidewall of the back side contact BC may include a portion in which the width in the second horizontal direction (Y direction) is discontinuously increased. That is, the back side contact BC may include the stepped portion between the first portion BC_1 and the second portion BC_2. For example, the width L1 of the first portion BC_1 of the back side contact (BC) in the second horizontal direction (Y direction) may be greater than or equal to about 20 nm and less than about 30 nm, and the width L2 of the second portion BC_2 of the back side contact BC in the second horizontal direction (Y direction) may be greater than or equal to about 30 nm and less than or equal to about 50 nm. In some embodiments, the sidewall of the back side contact BC may include a portion in which a width continuously increases in the first horizontal direction (X direction).

As illustrated in FIGS. 2 and 3B, the back side contact BC may be positioned in a first trench T1 and a second trench T2. The first trench T1 may be defined by the device isolation layer 112. The second trench T2 may penetrate the substrate 102. A width L3 of the first trench T1 in the second horizontal direction (Y direction) may be smaller than a width L4 of the second trench T2 in the second horizontal direction (Y direction).

In some embodiments, the width L3 of the first trench T1 in which the back side contact BC is positioned in the second horizontal direction (Y direction) may be the same as a width L5 of the fin-type active region F0 in the second horizontal direction (Y direction). Specifically, the width L3 of the first trench T1 in which the first portion BC_1 of the back side contact BC is positioned in the second horizontal direction (Y direction) may be the same as the width L5 of the fin-type active region F0 in the second horizontal direction (Y-direction) that is measured at the same vertical level (i.e., in the Z direction) as the width L3. For example, at the first vertical level LV1, the width L3 of the first trench T1 in the second horizontal direction (Y direction) may be the same as the width L5 of the fin-type active region F0 in the second horizontal direction (Y direction).

In some embodiments, the width L4 of the second trench T2 in which the back side contact BC is positioned in the second horizontal direction (Y direction) may be greater than the width L5 of the fin-type active region F0 in the second horizontal direction (Y direction). Specifically, the width L4 of the second trench T2 in which the second portion BC_2 of the back side contact BC is positioned in the second horizontal direction (Y direction) may be greater than the width L5 of the fin-type active region F0 in the second horizontal direction (Y direction).

In some embodiments, the back side contact BC may be electrically connected to the source/drain area 130 positioned on the fin-type active region F0. For example, the back side contact BC may be electrically connected to the source/drain area 130 in such a configuration that the first portion BC_1 is in contact with the source/drain area 130.

In some embodiments, as illustrated in FIG. 3A, an insulating liner 104 may be positioned on the sidewall of the back side contact BC. Specifically, the insulating liner 104 may be positioned between the sidewall of the back side contact BC and the fin-type active region F0. For example, an insulating liner 104 may be positioned between the sidewall of the back side contact BC and the second fin F2 and between the sidewall of the back side contact BC and the third fin F3.

In some embodiments, as illustrated in FIG. 3B, the insulating liner 104 may be positioned on the sidewall of the back side contact BC. Specifically, the insulating liner 104 may be positioned on a sidewall of the first portion BC_1 of the back side contact BC and on an upper surface and a sidewall of the second portion BC_2 of the back side contact BC. For example, the insulating liner 104 may be positioned between the sidewall of the first portion BC_1 of the back side contact BC and the device isolation layer 112. For example, the insulating liner 104 may be positioned between the upper surface of the second portion BC_2 of the back side contact BC and the device isolation layer 112. That is, the insulating liner 104 may not be positioned at a portion where the upper surface of the second portion BC_2 of the back side contact BC makes contact with the first portion BC_1. For example, the insulating liner 104 may be positioned between the sidewall of the second portion BC_2 of the back side contact BC and the substrate 102. That is, the insulating liner 104 may be positioned on a second surface T1_2 of the first trench T1 and a first surface T2_1 and a second surface T2_2 of the second trench T2. The insulating liner 104 may include an insulating material, such as, for example, a silicon oxide layer, a silicon oxynitride layer, a silicon nitride layer, or a combination thereof, although embodiments of the invention are not limited to any specific insulating material forming the insulating liner 104.

In some embodiments, a first metal silicide layer 106 may be arranged on the upper surface of the back side contact BC. Specifically, the first metal silicide layer 106 may be positioned on the upper surface of the first portion BC_1 of the back side contact BC. For example, the first metal silicide layer 106 may be positioned between the back side contact BC and the source/drain area 130 that is positioned on the back side contact BC. That is, the first metal silicide layer 106 may be positioned on the first surface T1_1 of the first trench T1.

The first metal silicide layer (106) may include a metal, such as Ti, W, Ru, Nb, Mo, Hf, Ni, Co, Pt, Yb, Tb, Dy, Er, or Pd. For example, the first metal silicide layer 106 may include titanium silicide, but is not limited thereto. The first silicide layer may be formed using a known silicide formation process.

As illustrated in FIGS. 2, 3A, and 3B, the integrated circuit device 100 may include a back side conductive layer BM that is arranged on the second surface 102_2 of the substrate 102 and extends in the first horizontal direction (X direction). The back side conductive layer BM may be positioned on the back side contact BC at the same level of the second surface 102_2 of the substrate 102. The back side conductive layer BM may be surrounded by a back side insulating layer 109 in the second horizontal direction (Y direction). The term “surround” (“surrounding” or “surrounded”) as may be used herein is intended to broadly refer to a component, structure or layer that envelops, encircles, or encloses another component, structure or layer on all sides, although breaks or gaps may also be present. Thus, for example, a material layer having voids therein may still “surround” another layer which it encircles.

In some embodiments, the back side conductive layer BM may include a metal wiring layer and a conductive barrier layer enclosing the metal wiring layer. Regarding the detailed structure of the metal wiring layer and the conductive barrier layer of the back side conductive layer BM, the descriptions of the metal wiring layer and the conductive barrier layer of the back side contact BC may be referred to.

In some embodiments, the back side conductive layer BM may be electrically connected to the back side contact BC. The back side contact BC may link an electrical connection between the back side conductive layer BM and the source/drain area 130.

In some embodiments, the width of the back side conductive layer BM in the second horizontal direction (Y direction) may be greater than the width L1 of the first portion BC_1 in the second horizontal direction (Y direction) and may be smaller than the width L2 of the second portion BC_2 of the back side contact BC in the second horizontal direction (Y direction). However, this is only an example, and in some other embodiments, the width of the back side conductive layer BM in the second horizontal direction (Y direction) may be smaller than the width L1 of the first portion BC_1 of the back side contact BC in the second horizontal direction (Y direction). Otherwise, in some other embodiments, the width of the back side conductive layer BM in the second horizontal direction (Y direction) may be greater than the width L2 of the second portion BC_2 of the back side contact BC in the second horizontal direction (Y direction).

In some embodiments, the back side conductive layer BM may overlap with the back side contact BC in the vertical direction (Z direction). Specifically, the back side conductive layer BM may overlap with the first portion BC_1 of the back side contact BC in the vertical direction (Z direction). Specifically, the back side conductive layer BM may overlap with the second portion BC_2 of the back side contact BC in the vertical direction (Z direction).

A gate dielectric layer 152 may be positioned between the nanosheet stack NSS and the gate line 160. In some embodiments, the gate dielectric layer 152 may include a stack structure of an interface dielectric layer and a high dielectric layer (not explicitly shown, but implied). The interface dielectric layer may include a low dielectric material layer with permittivity of about 9 or less, such as, for example, a silicon oxide layer, a silicon oxynitride layer, and a combination thereof. In some embodiments, the interface dielectric layer may be omitted. The high dielectric layer may include, for example, a material having a higher dielectric constant than the interface dielectric layer. For example, the high dielectric layer may have a dielectric constant of about 10 to about 25. The high dielectric layer may include hafnium oxide, but is not limited thereto.

As illustrated in FIGS. 3A and 3C, a capping insulating pattern 168 may be arranged on upper surfaces of the gate dielectric layer 152 and the gate line 160. The capping insulating pattern 168 may include a silicon nitride layer.

An outer insulating spacer 118 may be arranged on both sidewalls of the gate line 160 and the capping insulating pattern 168. The outer insulating spacer 118 may cover both sidewalls of the main gate portion 160M on the upper surface of a plurality of nanosheet stacks NSS. The outer insulating spacer 118 may be spaced apart from the gate line 160 with the gate dielectric layer 152 interposed therebetween.

As illustrated in FIG. 3B, a plurality of recess-side insulating spacers 119 may be positioned on the upper surface of the device isolation layer 112 in such a configuration that the sidewalls of at least a portion of the source/drain area 130 are covered with the recess-side insulating spacers 119. In some embodiments, each recess-side insulating spacer 119 may be integrally connected to the neighboring outer insulating spacer 118.

The outer insulating spacer 118 and the recess-side insulating spacer 119 may include, for example, silicon nitride, silicon oxide, silicon carbon nitride (SiCN), silicon boron nitride (SiBN), silicon oxynitride (SiON), silicon oxycarbon nitride (SiOCN), silicon boron carbon nitride (SiBCN), silicon oxycarbide (SiOC), or a combination thereof, although embodiments of the invention are not limited thereto. The terms “SiCN”, “SiBN”, “SiON”, “SiOCN”, “SiBCN”, and “SiOC” used in this specification refer to materials made of elements in each of the terms, and are not a chemical formula representing a stoichiometric relationship.

A second metal silicide layer 172 may be positioned on the upper surfaces of each of the source/drain areas 130. The second metal silicide layer 172 may include a metal, such as Ti, W, Ru, Nb, Mo, Hf, Ni, Co, Pt, Yb, Tb, Dy, Er, or Pd. For example, the second metal silicide layer 172 may include titanium silicide, but is not limited thereto.

A plurality of source/drain areas 130, a plurality of second metal silicide layers 172, and a plurality of outer insulating spacers 128 may be covered with an insulating liner 142 on the substrate 102. In some embodiments, the insulating liner 142 may be omitted. An inter-gate insulating layer 144 may be positioned on the insulating liner 142. When the insulating liner 142 is omitted, the inter-gate insulating layer 144 may make contact with the plurality of source/drain areas 130.

The insulating liner 142 and the inter-gate insulating layer 144 may be sequentially positioned on the plurality of source/drain areas 130 and the plurality of second metal silicide layers 172. The insulating liner 142 and the inter-gate insulating layer 144 may be configured as an insulating structure. In some embodiments, the insulating liner 142 may include, for example, silicon nitride, SiCN, SiBN, SiON, SiOCN, SiBCN, or a combination thereof, but is not limited thereto. The inter-gate insulating layer 144 may include, for example, a silicon oxide layer, but is not limited thereto.

Both sidewalls of each sub-gate portion 160S of the plurality of gate lines 160 may be spaced apart from the source/drain area 130 with the gate dielectric layer 152 positioned therebetween. The gate dielectric layer 152 may be positioned between the sub-gate portion 160S of the gate line 160 and each of the first nanosheet N1, the second nanosheet N2, and the third nanosheet N3, and between the sub-gate portion 160S of the gate line 160 and the source/drain area 130.

A plurality of nanosheet stacks NSS may be positioned on the fin upper surface FT of each fin-type active region F0 in areas where the plurality of fin-type active regions F0 and the plurality of gate lines 160 cross with one another, and may face the fin upper surface FT of the fin-type active region F0 at a position spaced apart from the fin-type active region F0. A plurality of nanosheet transistors may be arranged in cross areas where the plurality of fin-type active regions F0 and the plurality of gate lines 160 cross with one another on the substrate 102.

As illustrated in FIGS. 3A and 3B, a plurality of source/drain contacts CA may be positioned on the plurality of source/drain areas 130. The plurality of source/drain contacts CA may penetrate the inter-gate insulating layer 144 and the insulating liner 142 in the vertical direction (Z direction), to thereby make contact with the second metal silicide layer 172, respectively. Each source/drain contact CA may be electrically connected to the source/drain area 130 through the second metal silicide layer 172. Each source/drain contact CA may be spaced apart from the main gate portion 160M in the first horizontal direction (X direction) with the outer insulating spacer 118 positioned therebetween, respectively.

Each source/drain contact CA may include a conductive barrier pattern 174 and a contact plug 176 that are sequentially stacked on the source/drain area 130. The conductive barrier pattern 174 may enclose the contact plug 176 (which is also be conductive) in such a configuration that the conductive barrier pattern 174 may make contact with a bottom surface and a sidewall of the contact plug 176. Each source/drain contact CA may extend along in the vertical direction (Z direction) through the inter-gate insulating layer 144 and the insulating liner 142. The conductive barrier pattern 174 may be positioned between the second metal silicide layer 172 and the contact plug 176. The conductive barrier pattern 174 may have a surface portion making contact with the second metal silicide layer 172 and another surface portion making contact with the contact plug 176. In one or more embodiments, the conductive barrier pattern 174 may include, for example, a metal or a metal nitride. Examples of the conductive barrier pattern 174 may include, for example, Ti, Ta, W, TiN, TaN, tungsten nitride (WN), tungsten carbon nitride (WCN), titanium silicon nitride (TiSiN), tantalum silicon nitride (TaSiN), tungsten silicon nitride (WSiN), or a combination thereof, but is not limited thereto. The contact plug 176 may include, for example, Mo, copper (Cu), W, Co, Ru, manganese (Mn), Ti, Ta, aluminum (Al), a combination thereof, and an alloy thereof, but is not limited thereto.

As illustrated in FIGS. 3A to 3C, upper surfaces of the plurality of source/drain contacts CA, a plurality of capping insulating patterns 168 and the inter-gate insulating layer 144 may be covered with an upper insulating structure 180. The upper insulating structure 180 may include an etching stop layer 182 and an interlayer insulating layer 184 that are sequentially stacked on the plurality of source/drain contacts CA, the plurality of capping insulating patterns 168, and the inter-gate insulating layer 144. The etching stop layer 182 may include, for example, SiC, silicon nitride (SiN), nitrogen-doped silicon carbide (SiC:N), SiOC, aluminum nitride (AlN), aluminum oxynitride (AlON), aluminum oxide (AlO), aluminum oxycarbonide (AIDC), or a combination thereof, although embodiments of the invention are not limited thereto. The interlayer insulating layer 184 may include, for example, an oxide layer, a nitride layer, an ultra low-k (ULK) layer with an ultra-low dielectric constant K of about 2.2 to about 2.4, or a combination thereof, although embodiments of the invention are not limited thereto. For example, the interlayer insulating layer 184 may include a tetraethyl orthosilicate (TEOS) layer, a high-density plasma (HDP) oxide layer, a boro-phospho-silicate glass (BPSG) layer, a flowable chemical vapor deposition (FCVD) oxide layer, a SiON layer, a SiN layer, a SiOC layer, a silicon carbon oxyhydrogel (SiCOH) layer, or a combination of thereof, but is not limited thereto.

As illustrated in FIGS. 3A and 3B, a plurality of source/drain via contacts VA may be positioned on the plurality of source/drain contacts CA. Each of the plurality of source/drain via contacts VA may make contact with a corresponding one of the source/drain via contacts CA, respectively, penetrating through the upper insulating structure 180. The plurality of source/drain areas 130 may be electrically connected to the plurality of source/drain via contacts VA via the second metal silicide layer 172 and the source/drain contact CA, respectively. A bottom surface of each source/drain via contact VA may be in contact with an upper surface of the source/drain contact CA. Each source/drain via contact VA may include Mo or W, but is not limited thereto.

As illustrated in FIGS. 2 and 3C, a gate contact CB may be positioned on the gate line 160. The gate contact CB may be connected to the gate line 160, extending through the upper insulating structure 180 and the capping insulating pattern 168 in the vertical direction (Z direction). A bottom surface of the gate contact CB may make contact with an upper surface of the gate line 160. The gate contact CB may include, for example, a contact plug made of Mo, Cu, W, Co, Ru, Mn, Ti, Ta, Al, a combination thereof, or an alloy thereof, but the material of the contact plug is not limited to the examples. In some embodiments, the gate contact CB may further include a conductive barrier pattern (not explicitly shown, but implied) partially enclosing the contact plug. The conductive barrier pattern of the gate contact CB may include a metal or a metal nitride. For example, the conductive barrier pattern may include Ti, Ta, W, TiN, TaN, WN, WCN, TiSiN, TaSiN, WSiN, or a combination thereof, but is not limited thereto.

A plurality of upper wiring layers M1 may be positioned in such a configuration that the upper wiring layers M1 penetrate an upper insulating layer 192 which may be formed on an upper surface of the upper insulating structure 180 and source/drain via contacts VA, such as by using a metallization process. Each of at least a portion of the upper wiring layers M1 may extend through the upper insulating layer 192 in a vertical direction (Z direction) and for connection to a corresponding one of the source/drain via contact VA, which is selected from the plurality of source/drain via contacts VA, and the gate contact CB, which is selected from the plurality of gate contacts CB (refer to FIG. 2). The upper wiring layers M1 may include, for example, Mo, Cu, W, Co, Ru, Mn, Ti, Ta, Al, a combination thereof, or an alloy thereof, but are not limited thereto.

That is, according to some embodiments of the integrated circuit device 100 described with reference to FIGS. 2 and 3A to 3C, the back side contact BC may be provided in such a configuration that the first portion BC_1 and the second portion BC_2 has different widths in a second horizontal direction (Y-direction). That is, according to some embodiments of the integrated circuit device 100 described with reference to FIGS. 2 and 3A to 3C, the first portion BC_1 and the second portion BC_2 of the back side contact BC is defined by the device isolation layer 112 and the substrate 102, and the widths of the first portion BC_1 and the second portion BC_2 in the second horizontal direction (Y direction) may be different from each other.

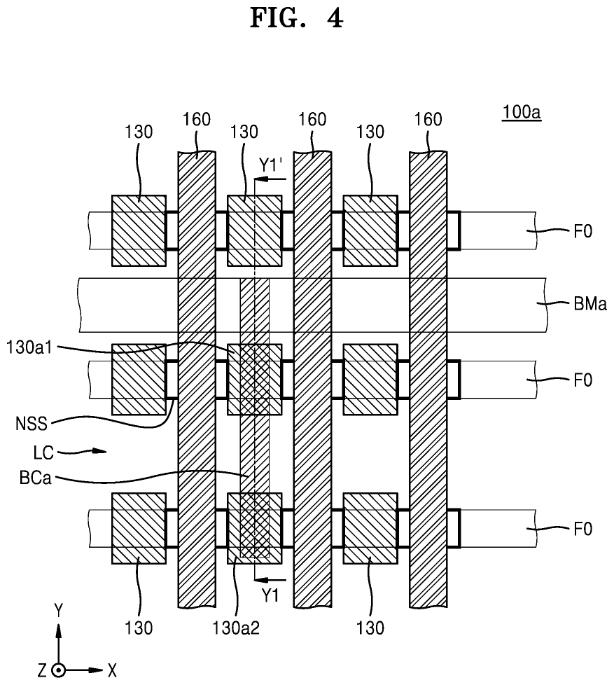

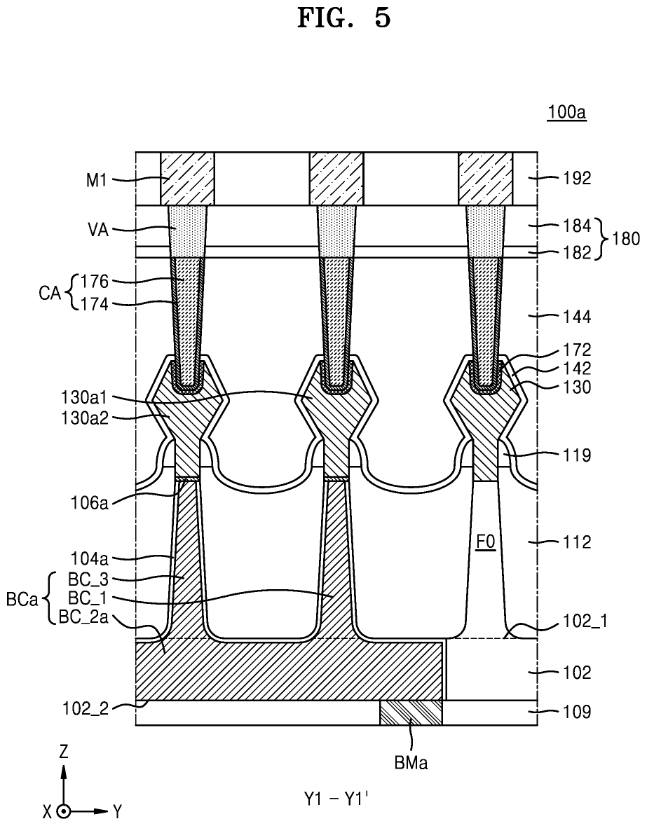

FIG. 4 is a plan view showing a planar layout of an integrated circuit device 100a according to another embodiment. FIG. 5 is a cross-sectional view illustrating the integrated circuit device 100a according to another embodiment. Specifically, FIG. 5 is a cross-sectional view taken along a line Y1-Y1′ in FIG. 4.

The integrated circuit device 100a is described hereinafter with reference to FIGS. 4 and 5 mainly with the differences from the integrated circuit device 100 that is described in detail with reference to FIGS. 2 and 3A to 3C.

As shown in FIGS. 4 and 5, the integrated circuit device 100a may include a back side contact BCa overlapping with a plurality of fin-type active regions F0 in a first horizontal direction (X direction) and a second horizontal direction (Y direction). Specifically, the back side contact BCa may include a first portion BC_1 and a third portion BC_3 protruding from on the first surface 102_1 of the substrate 102 in a vertical direction (Z direction). Specifically, the back side contact BCa may further include a second portion BC_2a penetrating through the substrate 102 and positioned at the same vertical level as the substrate 102.

In some embodiments, the first portion BC_1 and the third portion BC_3 of the back side contact BCa may be spaced apart from each other in the second horizontal direction (Y direction) with the device isolation layer 112 disposed therebetween. The first portion BC_1 and the third portion BC_3 of the back side contact BCa may overlap with each other in the second horizontal direction (Y direction). The second portion BC_2a of the back side contact BCa may extend in the second horizontal direction (Y direction) at the same vertical level as the substrate 102.

In some embodiments, a width of the first portion BC_1 of the back side contact BCa in the second horizontal direction (Y direction) may be substantially the same as that of the third portion BC_3 in the second horizontal direction (Y direction), although in other embodiments, the width of the first portion BC_1 of the back side contact BCa in the second horizontal direction (Y direction) may be different relative to the width of the third portion BC_3 of the back side contact BCa. In some embodiments, the width of the first portion BC_1 or the third portion BC_3 of the back side contact BCa in the second horizontal direction (Y direction) may be smaller than that of the second portion BC_2a in the second horizontal direction (Y direction). In some embodiments, the sum of the widths of the first portion BC_1 and the third portion BC_3 of the back side contact BCa in the second horizontal direction (Y direction) may be smaller than the width of the second portion BC_2a in the second horizontal direction (Y direction).

In some embodiments, the first portion BC_1 and the third portion BC_3 of the back side contact BCa may be electrically connected by the second portion BC_2a. The second portion BC_2a of the back side contact BCa may be electrically connected to the first portion BC_1 and the third portion BC_3. The second portion BC_2a of the back side contact BCa may overlap with the first portion BC_1 and the third portion BC_3 in the vertical direction (Z direction).

In some embodiments, the first portion BC_1 of the back side contact BCa may be electrically connected to a source/drain area 130a1 that is arranged on the first portion BC_1. The third portion BC_3 of the back side contact BCa may be electrically connected to a source/drain area 130a2 that is arranged on the third portion BC_3. That is, the source/drain area 130a1 on the first portion BC_1 and the source/drain area 130a2 on the third portion BC_3 may be electrically connected to each other by the back side contact BCa. Specifically, the source/drain area 130a1 on the first portion BC_1 and the source/drain area 130a2 on the third portion BC_3 may be electrically connected to each other by the first portion BC_1, the third portion BC_3, and the second portion BC_2a to which the first portion BC_1 and the third portion BC_3 are commonly connected. That is, the back side contact BCa may be electrically connected to a plurality of source/drain areas.

In some embodiments, an insulating liner 104a may be positioned on a sidewall of the back side contact BCa. Specifically, an insulating liner 104a may be disposed on a sidewall of the first portion BC_1 of the back side contact BCa, an upper surface and a sidewall of the second portion BC_2a of the back side contact BCa, and a sidewall of the third portion BC_3 of the back side contact BCa. For example, the insulating liner 104a may be positioned between the sidewall of the first portion BC_1 of the back side contact BCa and the device isolation layer 112. For example, the insulating liner 104a may be positioned between the upper surface of the second portion BC_2a of the back side contact BCa and the device isolation layer 112. That is, the insulating liner 104a may not be provided at connection portions at which the upper surface of the second portion BC_2a of the back side contact BCa makes contact with the first portion BC_1 and the third portion BC_3. For example, the insulating liner 104a may be positioned between the sidewall of the second portion BC_2a of the back side contact BCa and the substrate 102. For example, the insulating liner 104a may be positioned between the sidewall of the third portion BC_3 of the back side contact BCa and the device isolation layer 112.

In some embodiments, a first metal silicide layer 106a may be positioned on the upper surface of the back side contact BCa. Specifically, the first metal silicide layer 106a may be positioned (e.g., formed) on the upper surface of the first portion BC_1 of the back side contact BCa and the upper surface of the third portion BC_3 of the back side contact BCa. Like the first metal silicide layer 106, the first metal silicide layer 106a may include a metal, such as Ti, W, Ru, Nb, Mo, Hf, Ni, Co, Pt, Yb, Tb, Dy, Er, or Pd, although embodiments of the invention are not limited thereto.

Specifically, the first metal silicide layer 106a may be positioned between the back side contact BCa and the source/drain area 130 on the back side contact BCa. For example, the first metal silicide layer 106a may be positioned between the first portion BC_1 of the back side contact BCa and the source/drain area 130a1 that is positioned on the first portion BC_1. For example, the first metal silicide layer 106a may also be positioned between the third portion BC_3 of the back side contact BCa and the source/drain area 130a2 that is positioned on the third portion BC_3.

In some embodiments, the integrated circuit device 100a may include a back side conductive layer BMa positioned on the second surface 102_2 of the substrate 102 and extending in the first horizontal direction (X direction). Particularly, the back side conductive layer BMa may be positioned on the second surface 102_2 of the substrate 102 in such a configuration that the back side conductive layer BMa makes contact with the back side contact BCa. The back side conductive layer BMa may be defined by the back side insulating layer 109 in the second horizontal direction (Y direction).

In some embodiments, the back side conductive layer BMa may be electrically connected with the back side contact BCa (e.g., for providing electrical connection between the back side contact BCa and an external circuit or element). The back side contact BCa may link an electrical connection between the back side conductive layer BMa and the source/drain area 130. Specifically, the back side conductive layer BMa may be electrically connected to the source/drain area 130a1 that is positioned on the first portion BC_1 of the back side contact BCa. Specifically, the back side conductive layer BMa may be electrically connected to the source/drain area 130a2 that is positioned on the third portion BC_3 of the back side contact BCa. That is, the back side conductive layer BMa may be electrically connected to a plurality of source/drain areas by the back side contact BCa.

In some embodiments, a width of the back side conductive layer BMa in the second horizontal direction (Y direction) may be greater than the width of the first portion BC_1 of the back side contact BCa and smaller than the width of the second portion BC_2a of the back side contact BCa in the second horizontal direction (Y direction). However, this is only an example, and in some other embodiments, the width of the back side conductive layer BMa in the second horizontal direction (Y direction) may be smaller than the width of the first portion BC_1 of the back side contact BCa in the second horizontal direction (Y direction). In addition, in some other embodiments, the width of the back side conductive layer BMa in the second horizontal direction (Y direction) may be greater than the width of the second portion BC_2a of the back side contact BCa in the second horizontal direction (Y direction).

In some embodiments, the back side conductive layer BMa may overlap with the back side contact BCa in the vertical direction (Z direction). Specifically, the back side conductive layer BMa may overlap with the second portion BC_2a of the back side contact BCa in the vertical direction (Z direction). In some embodiments, the back side conductive layer BMa may not overlap with the first portion BC_1 of the back side contact BCa in the vertical direction (Z direction). However, this is only an example, and in some other embodiments, the back side conductive layer BMa may overlap with the first portion BC_1 of the back side contact BCa in the vertical direction (Z direction).

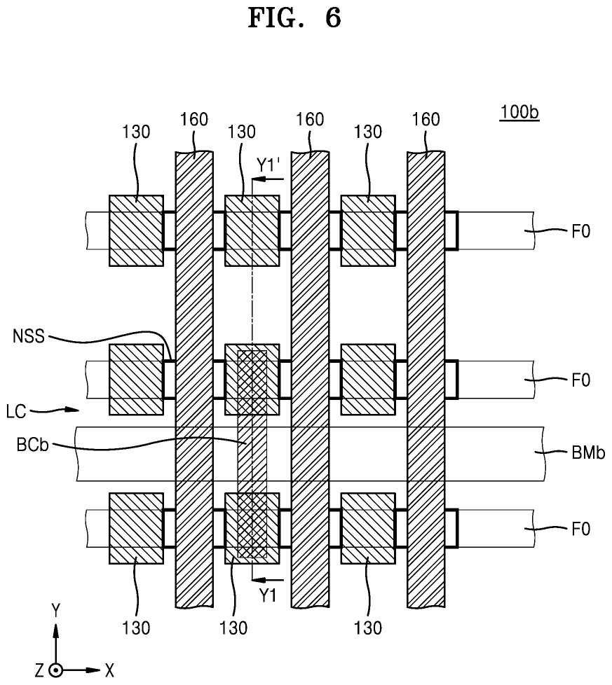

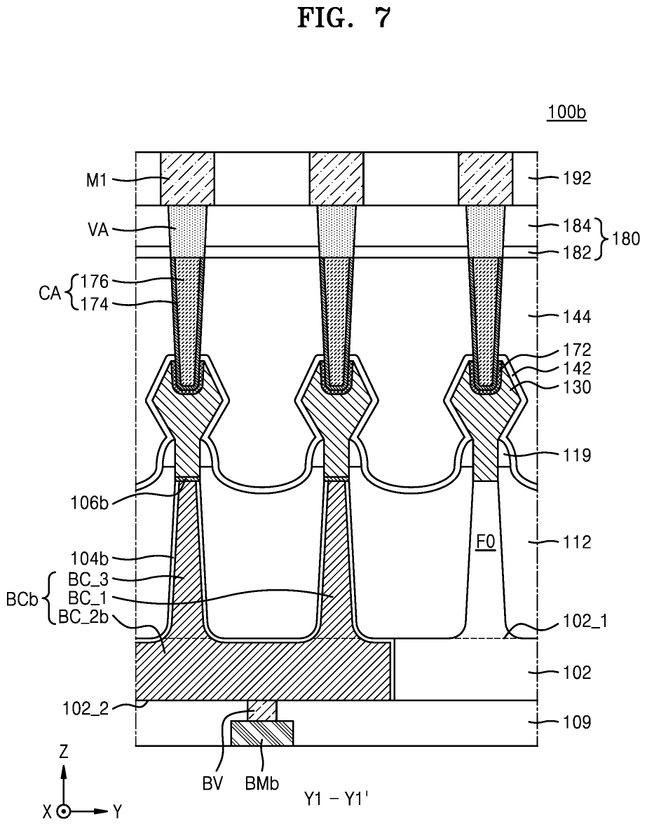

FIG. 6 is a diagram showing a planar layout of an integrated circuit device 100b according to another embodiment. FIG. 7 is a cross-sectional view illustrating an integrated circuit device 100b according to another embodiment. Specifically, FIG. 7 is a cross-sectional view taken along a line Y1-Y1′ in FIG. 6.

The integrated circuit device 100b is described hereinafter with reference to FIGS. 6 and 7 mainly with the differences from the integrated circuit device 100 that is described in detail with reference to FIGS. 2 and 3A to 3C.

As shown in FIGS. 6 and 7, the integrated circuit device 100b may include a back side contact BCb overlapping with a plurality of fin-type active regions F0 in a first horizontal direction(X direction) and a second horizontal direction(Y direction). Specifically, the back side contact BCb may include a first portion BC_1 and a third portion BC_3 protruding from on the first surface 102_1 of the substrate 102 in a vertical direction (Z direction). Specifically, the back side contact BCb may further include a second portion BC_2b penetrating through the substrate 102 and positioned at the same vertical level as the substrate 102. Regarding the description of the back side contact BCb of the integrated circuit device 100b, the descriptions of the back side contact BCa of the integrated circuit device 100a given with reference to FIGS. 4 and 5 may be referred to.

In some embodiments, the integrated circuit device 100b may include an insulating liner 104b extending on a sidewall of the back side contact BCb. Regarding the insulating liner 104b, the descriptions of the insulating liner 104a of the integrated circuit device 100a given with reference to FIGS. 4 and 5 may be referred to.

In some embodiments, the integrated circuit device 100b may include a first metal silicide layer 106b that is positioned on the upper surface and on the back side contact BCb. Regarding the first metal silicide layer 106b, the descriptions of the first metal silicide layer 106a of the integrated circuit device 100a given with reference to FIGS. 4 and 5 may be referred to.

In some embodiments, the integrated circuit device 100b may include a back side conductive layer BMb that is positioned on the second surface 102_2 of the substrate 102 and extends in the first horizontal direction (X direction). Regarding the back side conductive layer BMb, the descriptions of the back side conductive layer BMa on the integrated circuit device 100a given with reference to FIGS. 4 and 5 may be referred to.

In some embodiments, the integrated circuit device 100b may include a back side via BV positioned on the second surface 102_2 of the substrate 102 and extending at least partially through the back side insulating layer 109 in the vertical direction (Z direction). The back side via BV may be positioned on the second surface 102_2 of the substrate 102 in such a configuration that the back side via BV makes contact with the back side contact BCb. The back side via BV may be enclosed by the back side insulating layer 109 in the second horizontal direction (Y direction).

In some embodiments, the back side via BV may be electrically connected to the back side contact BCb. The back side via BV may provide an electrical connection between the back side conductive layer BMb and the back side contact BCb.

In some embodiments, the width of the back side via BV in the second horizontal direction (Y direction) may be smaller than the width of the second portion BC_2a of the back side contact BCa in the second horizontal direction (Y direction). In some embodiments, the width of the back side via BV in the second horizontal direction (Y direction) may be smaller than the width of the back side conductive layer BMb in the second horizontal direction (Y direction). However, this is only an example, and in some other embodiments, the width of the back side via BV in the second horizontal direction (Y direction) may be greater than the width of the back side conductive layer BMb in the second horizontal direction (Y direction).

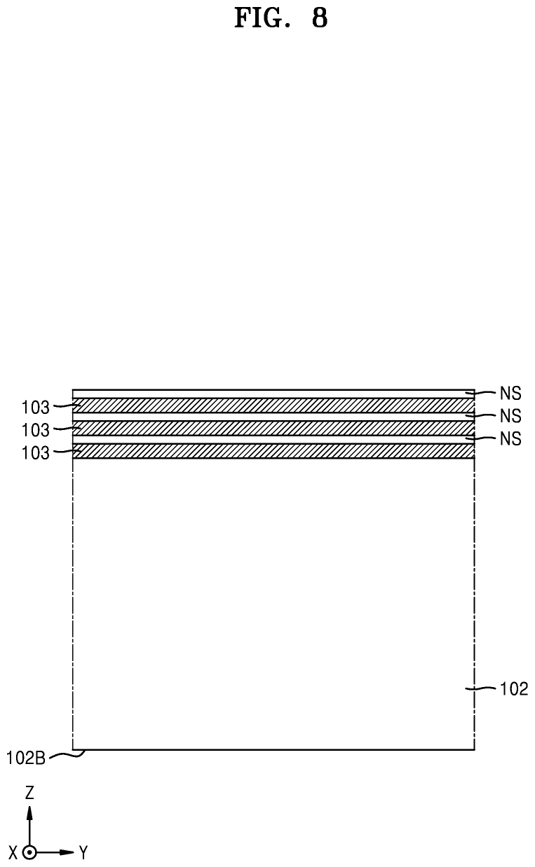

FIGS. 8 to 19 are cross-sectional views illustrating intermediate processes in an example method of manufacturing an integrated circuit device according to an embodiment, in a process order. Specifically, FIGS. 8 to 19 are cross-sectional views sequentially illustrating exemplary cross-sectional structures corresponding to a cross-section taken along a line Y1-Y1′ in FIG. 2 according to a process sequential order.

Referring to FIG. 8, a plurality of sacrificial semiconductor layers 103 and a plurality of nanosheet semiconductor layers NS may be alternately stacked on the substrate 102.

The plurality of sacrificial semiconductor layers 103 and the plurality of nanosheet semiconductor layers NS may include semiconductor materials having different etching selectivity. In some embodiments, the plurality of nanosheet semiconductor layers NS may include a silicon (Si) layer, and the plurality of sacrificial semiconductor layers 103 may include a silicon germanium (SiGe) layer. In embodiments, the amount of germanium (Ge) may be constant in the plurality of sacrificial semiconductor layers 103. The silicon germanium (SiGe) layer of the plurality of sacrificial semiconductor layers 103 may have a constant amount of germanium (Ge) that is selected in a range of about 5 at % to about 60 at %, and more particularly, of about 10 at % to about 40 at %. The amount of germanium (Ge) in the silicon germanium (SiGe) layer of the plurality of sacrificial semiconductor layers 103 may be variously selected as necessary.

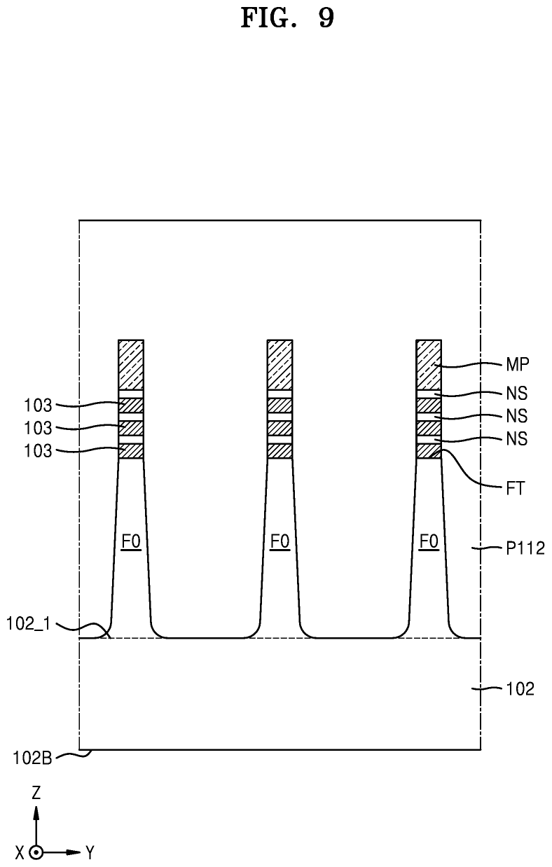

Referring to FIG. 9, a mask pattern MP (e.g., patterned photoresist layer) may be formed on a resultant product shown in FIG. 8, and then a plurality of fin-type active regions F0 may be formed on the substrate 102 by partially etching the plurality of sacrificial semiconductor layers 103, the plurality of nanosheet semiconductor layers NS, and the substrate 102 by using the mask pattern MP as an etching mask. Thus, the first surface 102_1 of the substrate 102 may be formed, and the plurality of fin-type active regions F0 may be arranged on the first surface 102_1. In some embodiments, the mask pattern MP may include a stack structure including an oxide layer pattern and a silicon nitride layer pattern. The mask pattern MP may extend in the first horizontal direction (X direction) in parallel over the substrate 102. Thus, the stack structure having the plurality of sacrificial semiconductor layers 130 and the plurality of nanosheet semiconductor layers NS may remain on the fin upper surface FT of each fin-type active region F0.

Thereafter, a device isolation insulating layer P112 covering the mask pattern MP, the plurality of nanosheet semiconductor layers NS, and the plurality of fin-type active regions F0 may be formed on the first surface 102_1 of the substrate 102. For example, the device isolation insulating layer P112 may include a silicon oxide layer. The device isolation insulating layer P112 may be formed by any one of a plasma enhanced chemical vapor deposition (PECVD) process, a high-density plasma CVD (HDP-CVD) process, an inductively coupled plasma CVD (ICP-CVD) process, a capacitor coupled plasma CVD (CCP CVD) process, a flowable chemical vapor deposition (FCVD) process, a spin coating process, etc.

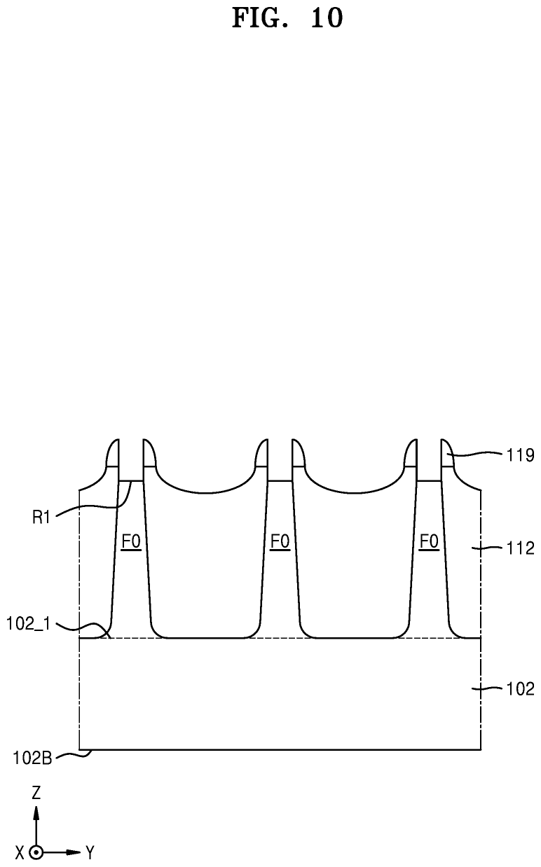

Referring to FIG. 10, the device isolation insulating layer P112 in FIG. 9 may be planarized (e.g., using a chemical-mechanical polishing/planarization (CMP) process or the like) until an upper surface of the mask pattern MP is exposed, and then the mask pattern MP that is exposed may be removed, and a recess process for removing a portion of the device isolation insulating layer P112 may be performed to thereby form a device isolation layer 112 on the first surface 102_1 of the substrate 102. Accordingly, the plurality of patterned sacrificial semiconductor layers 103 and the plurality of nanosheet semiconductor layers NS (refer to FIG. 9) may be protruded from the upper surface of the device isolation layer 112. It is to be appreciated that the term “exposed,” as may be used throughout the present specification to describe certain intermediate processes in fabricating a completed semiconductor device, is not intended to necessarily require exposure of the particular region, layer, structure or other element in the actual completed device.

In one or more embodiments, the recess process on the device isolation insulating layer P112 may be performed by a dry etching process, a wet etching process, or a combination of the dry etching and wet etching processes. For example, the wet etching process may be performed by using at least one of ammonium hydroxide (NH₄OH), tetramethyl ammonium hydroxide (TMAH), and potassium hydroxide (KOH) as an etchant, and the dry etching process may include an inductively coupled plasma (ICP) etching process, a transformer coupled plasma (TCP) etching process, an electron cyclotron radiation (ECR) etching process, a reactive ion etch (ME) etching process. When the dry etching process is performed on the device isolation insulating layer P112 as the recess process, a fluorine-containing gas such as CF₄, a chlorine-containing gas such as Cl₂, hydrogen bromide (HBr), etc. may be used as an etching gas.

After that, a portion of each of the plurality of patterned sacrificial semiconductor layers 103 and the plurality of nanosheet semiconductor layers NS and a portion of the fin-type active region F0 may be etched away, to thereby form a plurality of recesses R1 on an upper surface of each of the fin-type active regions F0. In one or more embodiments, so as to form the plurality of recesses R1, a dry etching process, a wet etching process, or a combination thereof may be used for etching. After forming the plurality of recesses R1, a plurality of recess-side insulating spacers 119 may be formed on the device isolation layer 112 at both sides of each fin-type active region F0 adjacent to the corresponding recess R1.

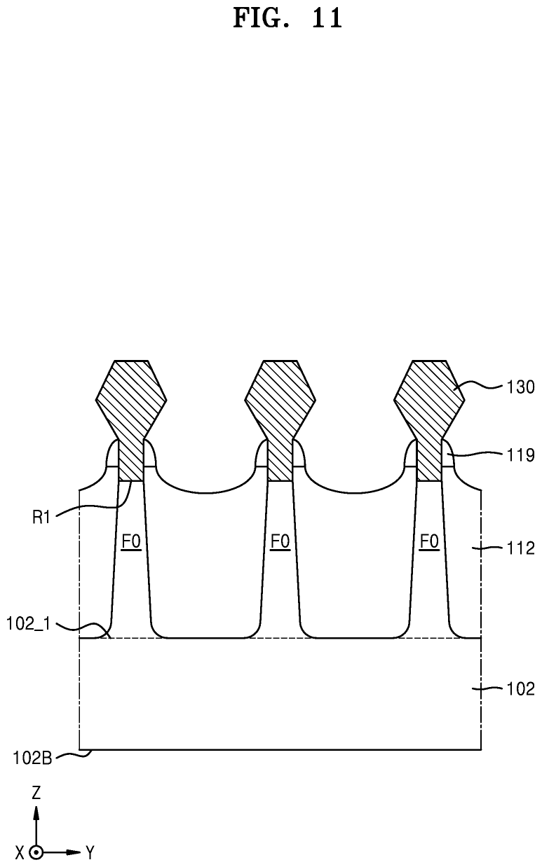

Referring to FIG. 11, a plurality of source/drain areas 130 may be formed on the resulting structure of FIG. 10 in such a way that the plurality of recesses R1 are filled with the plurality of source/drain areas 130, respectively. To form the plurality of source/drain areas 130, semiconductor materials may be epitaxially grown from a surface of each fin-type active region F0 that is exposed on a lower surface of the plurality of recesses R1. The term “filled” or “fill” as may be used herein is intended to refer to either completely filling a defined space (e.g., recesses R1) or partially filling the defined space; that is, the defined space need not be entirely filled but may, for example, be partially filled or have voids or other spaces throughout.

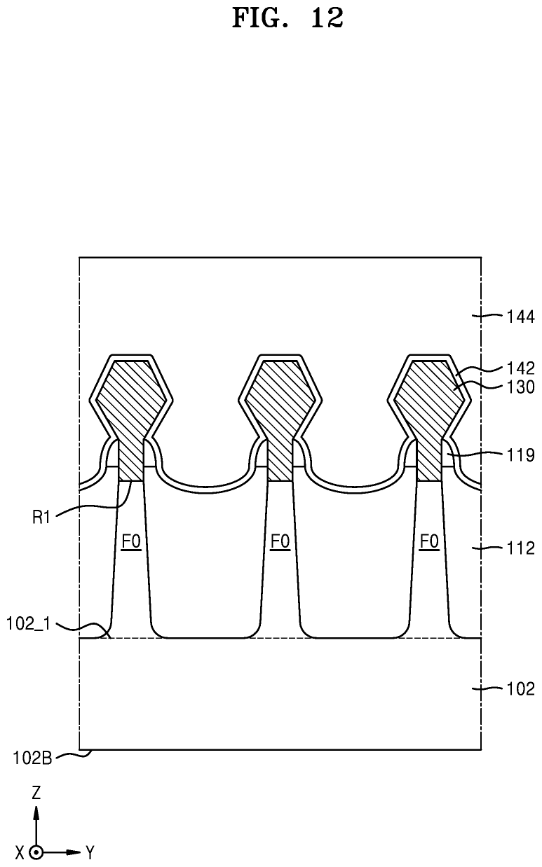

Referring to FIG. 12, an insulating liner 142 covering the resulting structure shown in FIG. 11 may be formed, and an inter-gate insulating layer 144 may be formed on the insulating liner 142.

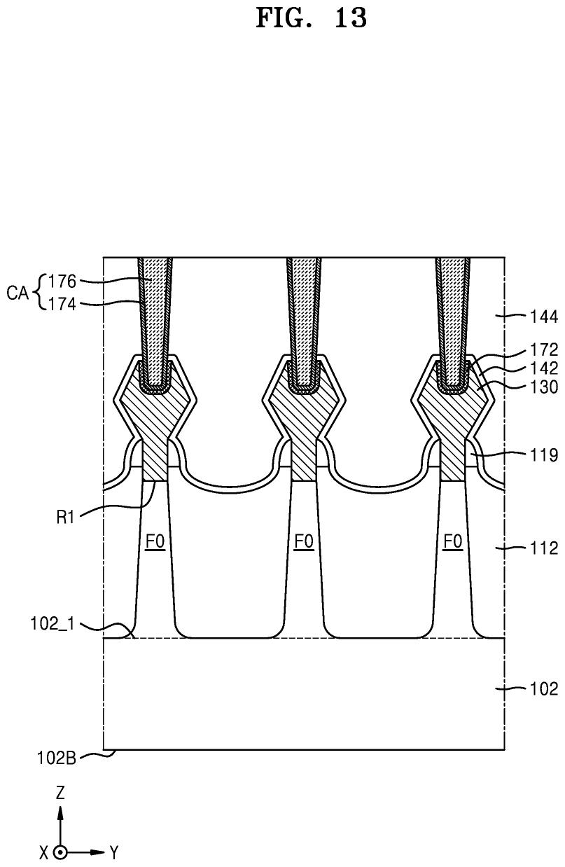

Referring to FIG. 13, a plurality of source/drain contact openings that penetrate through an insulation structure including the inter-gate insulating layer 144 and the insulating liner 142 in the vertical direction (Z direction) and expose the plurality of source/drain areas 130 are formed in the resulting structure shown in FIG. 12, and then a portion of each source/drain area 130 may be partially removed through the source/drain contact openings by an anisotropic etching process, to thereby expand the source/drain contact openings at least in a direction toward the substrate 102 (Z direction). Thereafter, a second metal silicide layer 172 may be formed on a surface of the source/drain area 130 that is exposed on bottom surfaces of the source/drain contact openings. In embodiments, to form the second metal silicide layer 172, a process may be performed, in which a metal liner (not explicitly shown, but implied) that conformally covers the exposed surface of the source/drain area 130 may be formed and heat treatment may be performed on the metal liner to induce a reaction between the source/drain area 130 and the metal of the metal liner. After forming the second metal silicide layer 172, the residuals of the metal liner may be removed. The source/drain area 130 may be partially consumed when forming the second metal silicide layer 172. In some embodiments, when the second metal silicide layer 172 includes a titanium silicide layer, the metal liner may include a titanium (Ti) layer.

Thereafter, a plurality of source/drain contacts CA including a conductive barrier pattern 174 and a contact plug 176 may be formed on each metal silicide layer 172.

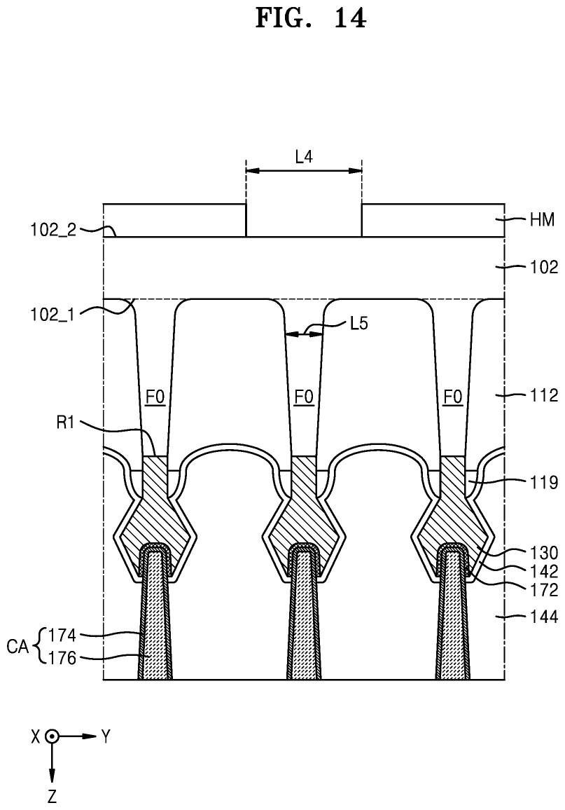

Referring to FIG. 14, the resulting structure shown in FIG. 13 may be turned over in the vertical direction (Z direction). Thereafter, a portion of the substrate 102 may be removed to form a second surface 102_2. For example, the second surface 102_2 may be formed by grinding the back side surface 102B (refer to FIG. 13) of the substrate 102. For example, the substrate 102 may be partially removed in such a way that the thickness of the substrate 102 is in a range of about 100 nm to about 300 nm in the vertical direction (Z direction). That is, the substrate 102 may be partially removed in such a configuration that a distance between the first surface 102_1 and the second surface 102_2 is about 100 nm to about 300 nm.

Thereafter, a hard mask layer HM may be formed on the second surface 102_2 of the substrate 102. The hard mask layer HM may be patterned and etched to expose a portion of the second surface 102_2 of the substrate 102. The exposed second surface 102_2, which is exposed through the hard mask layer HM, may partially overlap with the fin-type active regions F0 in the vertical direction (Z direction). In an embodiment, the width of the second surface 102_2 of the substrate 102 exposed through the hard mask layer HM is L4 in the second horizontal direction (Y direction), and L4 may be greater than a width L5 of the fin-type active region F0 in the second horizontal direction (Y direction).

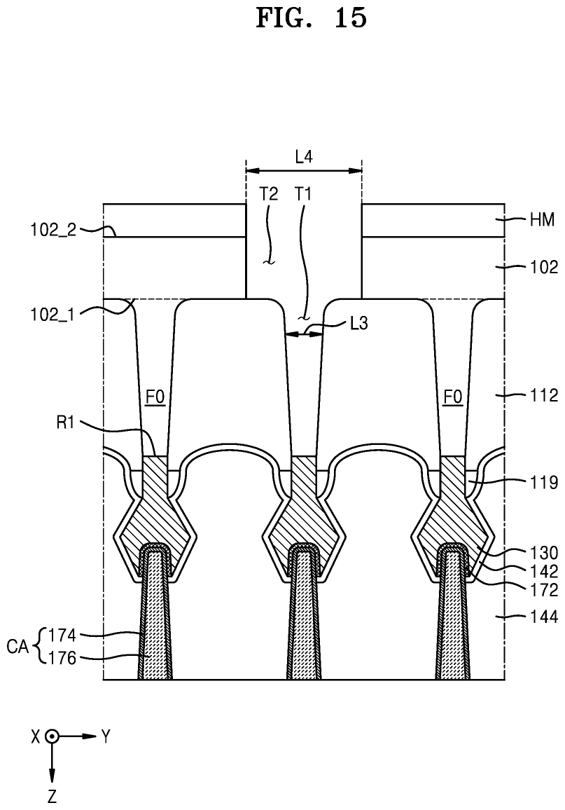

Referring to FIG. 15, the substrate 102 exposed by the hard mask layer HM may be at least partially etched to thereby form a second trench T2. Subsequently, the fin-type active region F0 exposed in the second trench T2 may be further etched away, to thereby form a first trench T1. The width L3 of the first trench T1 in the second horizontal direction (Y direction) may be smaller than the width L4 of the second trench T2 in the second horizontal direction (Y direction). In some embodiments, although not shown in FIG. 15, the source/drain area 130 may be partially etched in forming the first trench T1.

In some embodiments, the first trench T1 and the second trench T2 may be formed in a self-aligned manner. Specifically, the first trench T1 and the second trench T2 may be formed in a self-aligned manner by using a difference in etching selectivity between the substrate 102 and the device isolation layer 112. For example, without any additional etching mask patterns for the first trench T1 and the second trench T2, the second trench T2 may be formed using the hard mask layer HM, and the first trench T1 may be formed using the device isolation layer 112, which is exposed in the second trench T2, as an etching mask. Since, in one or more embodiments, there is a difference in etching selectivity between the device isolation layer 112 and the substrate 102, the device isolation layer 112 exposed in the second trench T2 may be used as a mask pattern to etch the substrate 102 and form the first trench T1. That is, by using the difference in the etching selectivity between the device isolation layer 112 and the substrate 102, the substrate 102 and the fin-type active region F0 may be selectively etched away, to thereby form the first trench T1 and the second trench T2.

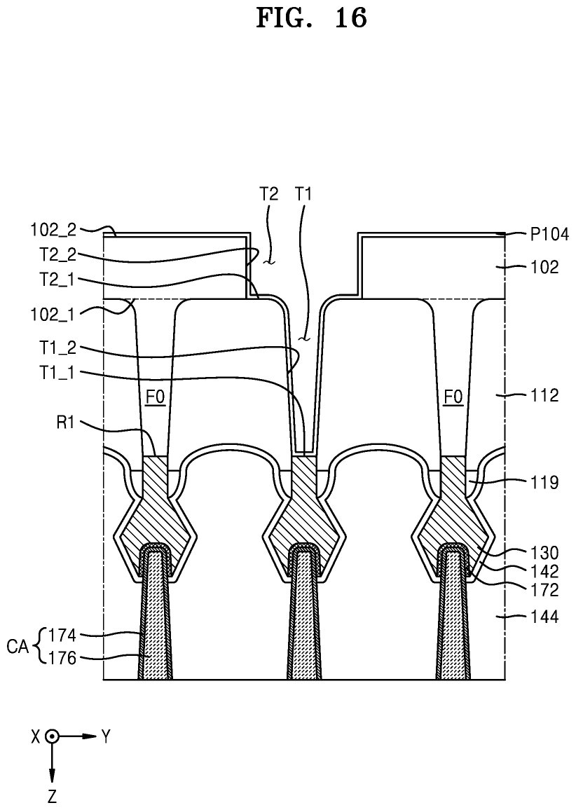

Referring to FIG. 16, a preliminary insulating liner P104 covering the resulting structure shown in FIG. 15 may be formed. Specifically, the preliminary insulating liner P104 may be formed on the second surface 102_2 of the substrate 102, a first surface T2_1 and a second surface T2_2 of the second trench T2, and a first surface T1_1 and a second surface T2_2 of the first trench T1. That is, the preliminary insulating liner P104 may be formed on the substrate 102, the device isolation layer 112, and the source/drain area 130 that are exposed in the first and second trenches T1 and T2.

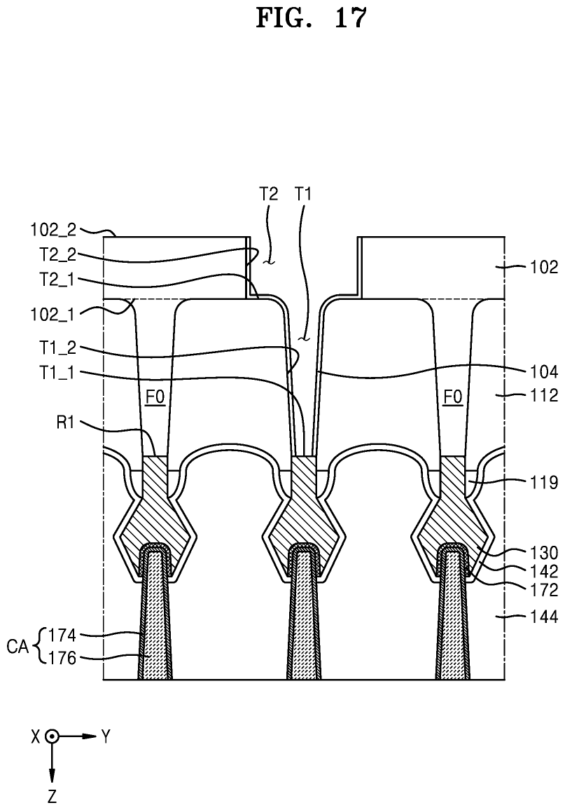

Referring to FIG. 17, the preliminary insulating liner P104 may be partially opened in the resulting structure shown in FIG. 16, to expose at least a portion of the source/drain area 130 therethrough, to thereby form an insulating liner 104. Specifically, the preliminary insulating liner P104 may be removed from the second surface 102_2 of the substrate 102, and may be removed from the first surface T1_1 of the first trench T1, to thereby expose the source/drain area 130. Thus, the insulating liner 104 may be formed on the second surface T2_2 of the first trench T1 and the first surface T2_1 and the second surface T2_2 of the second trench T2.

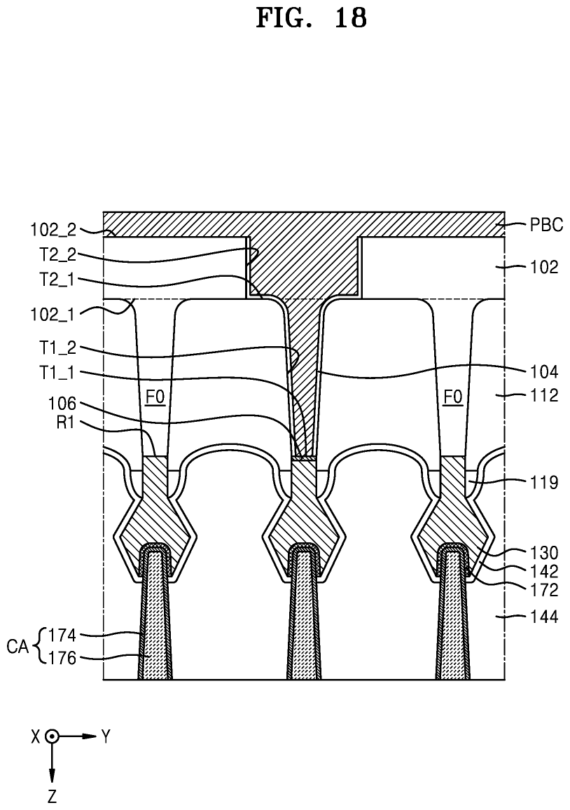

Referring to FIG. 18, a first metal silicide layer 106 may be formed. Specifically, the first metal silicide layer 106 may be formed on the first surface T1_1 of the first trench T1. That is, the first metal silicide layer 106 may be formed on the source/drain area 130 exposed by the first trench T1 and be defined by the insulating liner 104.

Thereafter, the preliminary back side contact PBC may be formed on the insulating liner 104 and the first metal silicide layer 106. Specifically, the preliminary back side contact PBC that covers the second surface 102_2 of the substrate 102 and fills the first trench T1 and the second trench T2 may be formed. For example, a preliminary conductive barrier layer (not explicitly shown, but implied) may be formed on the second surface 102_2 of the substrate 102, the first surface T1_1 and the second surface T1_2 of the first trench T1, and the first surface T2_1 and the second surface T2_2 of the second trench T2. Thereafter, a preliminary metal wiring layer (not explicitly shown, but implied) may be formed on the preliminary conductive barrier layer to form the preliminary back side contact PBC. That is, the preliminary back side contact PBC may be separated apart from the substrate 102 and the device isolation layer 112 with the insulating liner 104 therebetween. In addition, the preliminary back side contact PBC may be separated apart from the source/drain area 130 with the first metal silicide layer 106 therebetween.

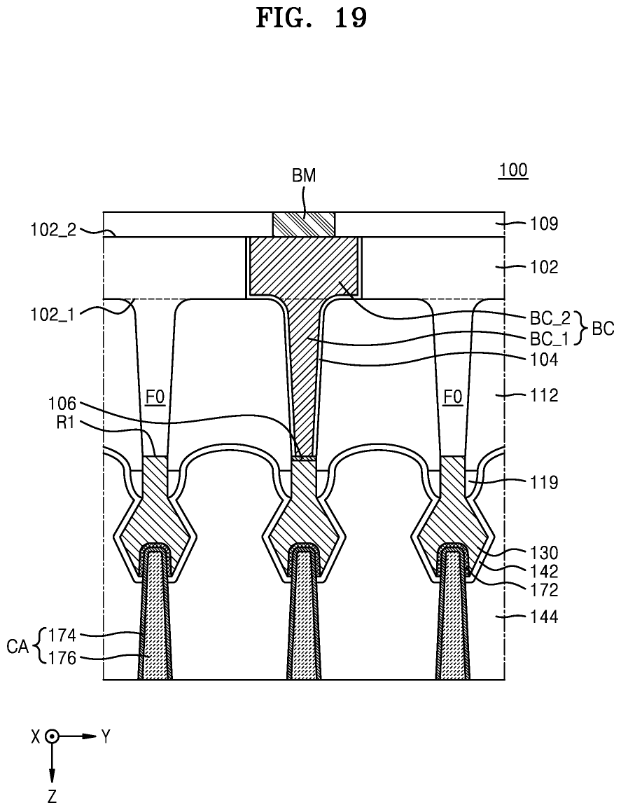

Referring to FIG. 19, the preliminary back side contact PBC on the second surface 102_2 of the substrate 102 may be partially removed to form a back side contact BC, and a back side conductive layer BM on the back side contact BC and the back side insulating layer 109 surrounding the same may be formed to thereby manufacture the integrated circuit device 100.

According to the method of manufacturing the integrated circuit device 100 described in detail with reference to FIGS. 8 to 19, the narrow fin-type active region F0 may be sufficiently etched away without any additional mask pattern for forming the first trench T1, to thereby provide the integrated circuit device 100 with improved reliability. That is, the integrated circuit device 100 may be manufactured with high reliability, as no additional mask pattern for forming the first trench T1 is required.

That is, according to the method of manufacturing the integrated circuit device 100 described in detail with reference to FIGS. 8 to 19, the first portion BC_1 of the back side contact BC may be formed without any additional mask pattern for forming the first portion BC_1 of the back side contact BC, which has a narrow width, and thus, the integrated circuit device 100 with improved reliability may be manufactured. That is, the back side contact BC may be formed in the integrated circuit device 100 having a smaller pitch, and thus, the integrated circuit device 100 having an improved integration degree may be provided.

Examples of the method of manufacturing the integrated circuit device 100 illustrated in FIGS. 2 and 3A to 3C has been described with reference to FIGS. 8 to 19, but those skilled in the art may know sufficiently well that the integrated circuit devices 100a and 100b illustrated in FIGS. 4 to 7 and integrated circuit devices having various structures modified and changed therefrom may be manufactured by applying various modifications and changes within the technical idea of the inventive concept.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Spatially descriptive terms such as “above,” “below,” “upper” and “lower” may be used herein to indicate a position of elements, structures or features relative to one another as illustrated in the figures, rather than absolute positioning. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Although the inventive concept has been described in detail with reference to preferred embodiments, the inventive concept is not limited to the above embodiment, and various modifications and changes may be made by those skilled in the art within the technical spirit and scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device, comprising:
a substrate having a first surface and a second surface, the second surface being opposite the first surface;
a first fin extending in a first horizontal direction on at least a portion of the first surface of the substrate;
a second fin spaced apart from the first fin in a second horizontal direction crossing the first horizontal direction, and extending in the first horizontal direction;
a third fin spaced apart from the second fin in the first horizontal direction and extending in the first horizontal direction at least partially overlapping the second fin in the first horizontal direction;
a first source/drain area on the first fin;
a second source/drain area on the second fin and the third fin and spaced apart from the first source/drain area in the second horizontal direction;
a back side contact between the second fin and the third fin and electrically connected to the second source/drain area; and
a back side conductive layer extending in the first horizontal direction on the second surface of the substrate and electrically connected to the back side contact,
wherein the back side contact includes a first portion protruding from the substrate and a second portion that is coplanar with the first surface of the substrate, and
wherein a width of the second portion of the back side contact in the second horizontal direction is greater than a width of the first portion in the second horizontal direction.

2. The integrated circuit device of claim 1, further comprising:
a plurality of gate lines spaced apart from each other in the first horizontal direction on the first fin, the second fin, and the third fin, and extending in the second horizontal direction,
wherein a distance between two adjacent gate lines of the plurality of gate lines is greater than a width of the back side contact in the first horizontal direction.

3. The integrated circuit device of claim 1, wherein
the back side conductive layer overlaps at least a portion of the back side contact in a vertical direction.

4. The integrated circuit device of claim 1, wherein
the back side conductive layer at least partially overlaps the first portion of the back side contact in a vertical direction.

5. The integrated circuit device of claim 1, wherein
the back side conductive layer is nonoverlapping, in a vertical direction, relative to the first portion of the back side contact.

6. The integrated circuit device of claim 1, further comprising
an insulating liner positioned on a sidewall of the back side contact.

7. The integrated circuit device of claim 1, wherein
a width of the first fin in the second horizontal direction is smaller than a width of the second portion of the back side contact in the second horizontal direction.

8. The integrated circuit device of claim 1, wherein
a width of the first portion of the back side contact in the second horizontal direction is 20 nm or more and less than 30 nm, and
a width of the second portion of the back side contact in the second horizontal direction is 30 nm or more and 50 nm or less.

9. The integrated circuit device of claim 1, wherein
the back side contact further comprises a third portion spaced apart from the first portion in the second horizontal direction and overlapping the first portion in the second horizontal direction,
wherein the second portion is electrically connected to the first portion and the third portion.

10. The integrated circuit device of claim 1, wherein
the first portion of the back side contact at least partially overlaps the first fin in the second horizontal direction.

11. An integrated circuit device, comprising:
a substrate having a first surface and a second surface, the first and second surfaces being opposite one another;
a fin-type active region extending in a first horizontal direction on the first surface of the substrate;
a plurality of gate lines extending in a second horizontal direction crossing the first horizontal direction on the fin-type active region and spaced apart from each other in the first horizontal direction;
a back side contact between the plurality of gate lines and overlapping the fin-type active region in the second horizontal direction;
a source/drain area on the back side contact; and
a back side conductive layer extending in the first horizontal direction on the second surface of the substrate,
wherein the back side contact is electrically connected to the source/drain area and the back side conductive layer,
the back side contact includes a first portion protruding from the substrate and a second portion that is coplanar with the first surface of the substrate, and
a width of the second portion in the second horizontal direction is greater than a width of the first portion in the second horizontal direction.

12. The integrated circuit device of claim 11, wherein
the back side conductive layer at least partially overlaps the back side contact in a vertical direction.

13. The integrated circuit device of claim 11, wherein
the back side conductive layer is nonoverlapping, in a vertical direction, relative to the first portion of the back side contact.

14. The integrated circuit device of claim 11, wherein
a width of the fin-type active region in the second horizontal direction is smaller than a width of the second portion of the back side contact in the second horizontal direction.

15. The integrated circuit device of claim 11, wherein
the back side contact further comprises a third portion spaced apart from the first portion in the second horizontal direction and at least partially overlaps the first portion in the second horizontal direction,
wherein the second portion is electrically connected to the first portion and the third portion.

16. An integrated circuit device, comprising:
a substrate having a first surface and a second surface, the second surface being opposite the first surface;
a fin-type active region extending in a first horizontal direction on the first surface of the substrate;
a plurality of nanosheets on the fin-type active region and spaced apart from an upper surface of the fin-type active region in a vertical direction;
a gate line surrounding the plurality of nanosheets on the fin-type active region and extending in a second horizontal direction crossing the first horizontal direction;
a back side contact on one side of the gate line and overlapping the fin-type active region in the second horizontal direction;
a first source/drain area on the fin-type active region and contacting the plurality of nanosheets;
a second source/drain area on the back side contact and contacting the plurality of nanosheets; and
a back side conductive layer extending in the first horizontal direction on the second surface of the substrate,
wherein the back side contact is electrically connected to the second source/drain area and the back side conductive layer,
the back side contact includes a first portion protruding from the substrate and a second portion that is coplanar with the first surface of the substrate, and
a width of the second portion in the second horizontal direction is greater than a width of the first portion in the second horizontal direction.

17. The integrated circuit device of claim 16, wherein
the back side conductive layer overlaps the first portion of the back side contact in a vertical direction.

18. The integrated circuit device of claim 16, wherein
the back side conductive layer is nonoverlapping, in a vertical direction, relative to the first portion of the back side contact.

19. The integrated circuit device of claim 16, wherein
a width of the fin-type active region in the second horizontal direction is smaller than a width of the second portion of the back side contact in the second horizontal direction.

20. The integrated circuit device of claim 16, further comprising
a metal silicide layer on an upper surface and a sidewall of the back side contact.
